(19) United States
(12) Patent Application Publication
(10) Pub. No.: US 2025/0253120 A1
(43) Pub. Date: Aug. 7, 2025

(54) ION IMPLANTATION SYSTEM AND METHOD OF OPERATION

(71) Applicant: Axcelis Technologies, Inc., Beverly, MA (US)

(72) Inventor: Yusef Nouri, Beverly, MA (US)

(21) Appl. No.: 19/040,897

(22) Filed: Jan. 30, 2025

Related U.S. Application Data
(60) Provisional application No. 63/548,899, filed on Feb. 2, 2024.

(51) Int. Cl. H01J 37/20; H01J 37/147; H01J 37/21; H01J 37/317

(52) U.S. Cl. CPC H01J 37/20; H01J 37/1474; H01J 37/21; H01J 37/3171; H01J 2237/0475; H01J 2237/20207; H01J 2237/20221; H01J 2237/30483; H01J 2237/31701

(57) ABSTRACT

An ion implantation system includes an ion source, a beamline that extracts and shapes an ion beam from the ion source, a deceleration stage that reduces the energy of the ion beam while focusing the ion beam in the direction of a workpiece. A workpiece support has a structure that determines an implant plane position, which is the position of a workpiece surface that receives the ion beam. The workpiece support is configured to translate the implant plane along a path of the ion beam so as to shorten or lengthen the path without changing the tilt angle of the workpiece. The beam optics may be fixed and the focal point of the ion beam may be allowed to vary with a decel ratio. The workpiece support may translate the implant plane to a focal point of the ion beam or to some fixed offset from that focal point.

### REFERENCE TO RELATED APPLICATIONS

This application claims the benefit of U.S. Provisional Application Ser. No. 63/548,899 filed Feb. 2, 2024, entitled, “ION IMPLANTATION SYSTEM AND METHOD OF OPERATION”, the contents of which are herein incorporated by reference in their entirety.

### BACKGROUND

Ion implantation systems are used in the integrated circuit (IC) device manufacturing industry to provide semiconductor wafers with controlled doses of impurities. A mask may be used to define a pattern for an impurity implant. Such factors as the depth of the implant, the concentration profile of the implant, and the uniformity of the implant across the wafer are dependent on the performance of ion implantation system. Manufacturing an IC device involves many ion implantations having various patterns, different types of impurities, varying concentrations, and various depths.

### BRIEF DESCRIPTION OF THE DRAWINGS

FIGS. 1A-1C illustrate a variation in focal length of an ion beam for high, medium, and low decel ratios, respectively, when the focal length is allowed to vary in accordance with the present disclosure.

FIGS. 2A-2C illustrate an embodiment in which a workpiece support of an ion implantation system moves a workpiece so that the implant plane is at the focal point of the ion beam for any of the focal lengths shown in FIGS. 1A-1C.

FIGS. 3A-3C illustrate an embodiment in which the workpiece support effectuates a y-direction scan on a tilted workpiece while maintaining the position of the implant plane.

FIG. 4 illustrates an ion implantation system in accordance with some aspects of the present disclosure.

FIG. 5 provides a flow chart for a method in accordance with some embodiments of the present disclosure.

FIGS. 6A-6C and 7 illustrate ion implantation systems in accordance with various embodiments where the ion implantation system has a detector for determining the position of an ion beam shadow cast by a workpiece when the ion beam travels over an edge of the workpiece.

FIGS. 8-10 provide flow charts for some additional methods provided by the present disclosure.

### DETAILED DESCRIPTION

The present disclosure provides many different embodiments, or examples, for implementing different features of this disclosure. Specific components and arrangements are provided to clarify and exemplify the disclosure. These specific examples should not be interpreted as limiting the scope of what is claimed.

One aspect of the present disclosure relates to an ion implantation system that provides an exceptionally high throughput rate for a class of damage engineering implants. A damage engineering implant may be used prior to an impurity implant to create a layer of disrupted crystalline structure. The disrupted crystalline structure may be repaired by annealing. Prior to any such repair, a dopant may be implanted. The layer of disrupted crystalline structure controls the depth of the dopant implant. An ion implantation system of the present disclosure enables an exceptionally high throughput rate for this type of damage engineering implant by providing high and well controlled beam current densities. The high and well controlled beam current densities are achieved by adjusting the implant plane position relative to the beam optics.

For dopant implantations, the throughput rate is primarily determined by the overall beam current. For damage engineering implants, however, it has been found that the efficiency with which the crystalline structure is disrupted can be greatly increased by increasing the beam current density even as the overall beam current remains constant. In addition to showing how throughput rate can be increased, this finding shows that controlling beam current density promotes uniformity for damage engineering implants.

An ion implantation system according to the present disclosure may include an ion source, a beamline that extracts and shapes an ion beam from the ion source, a deceleration stage that may reduce the energy of the ion beam while focusing the ion beam, and a workpiece support. The workpiece support has a structure that determines the implant plane position. The implant plant is the plane in which the ion beam will strike a workpiece held by the workpiece support. The implant plane position is determined by the distance along a path of the ion beam at which the ion beam encounters the workpiece. The orientation of the implant plane is determined by a tilt angle at which the workpiece support holds the workpiece. In accordance with the present disclosure, the workpiece support is configured to translate the implant plane along a path of the ion beam so as to shorten or lengthen the path without changing the tilt angle of the workpiece. In some embodiments, the workpiece support translates the implant plane to a focal point of the ion beam.

In some embodiments, the focal point of the ion beam is allowed to vary with a decel ratio. The decel ratio is a ratio of the ion beam's energy level before the deceleration stage to the ion beam's energy level after the deceleration stage. In some embodiments, the decel ratio is an operating parameter provided to the ion implantation system. In some embodiments, the decel ratio is specified as a function of a desired energy level for the ion beam after the deceleration stage, which is essentially what the ion beam's energy level will be at the implant plane (hereinafter “the implant beam energy”).

The depth of an ion implantation, whether it be an impurity implant or a damage engineering implant, depends on the implant beam energy. Accordingly, the implant beam energy is a user-specified operating parameter for an ion implantation system. The energy level of the ion beam before the deceleration stage (hereinafter “the beamline energy”) is generally determined independently from the implant beam energy.

Specifications for the beamline energy may be restricted to a comparatively narrow range. The beamline may include a mass analyzer, beam shaping apparatus, and beam steering apparatus. If the beamline energy is too high, beamline components such as the mass analyzer cannot function without being oversized and using excessive power. If the beamline energy is too low, beam blowout will occur. Beam blowout refers to circumstances in which the coherency of an ion beam is lost due to mutual repulsion between the ions in the ion beam. The lower the energy level of the ion beam, the slower moving the ions, and the more effect there is from the mutually repulsive forces of the like charged ions.

In some embodiments, the beam optics at and beyond the deceleration stage are not subject to tuning that is independent from the decel ratio so that the focal point of the ion beam varies continuously with the decel ratio. In principle, the beam optics could be adjusted to select the focal point of the ion beam. The inventor has found, however, that a more uniform and coherent ion beam can be provided if the implant plane is moved according to the decel ratio as opposed to adjusting the focusing optics to keep the focal point on a fixed position implant plane for all decel ratios.

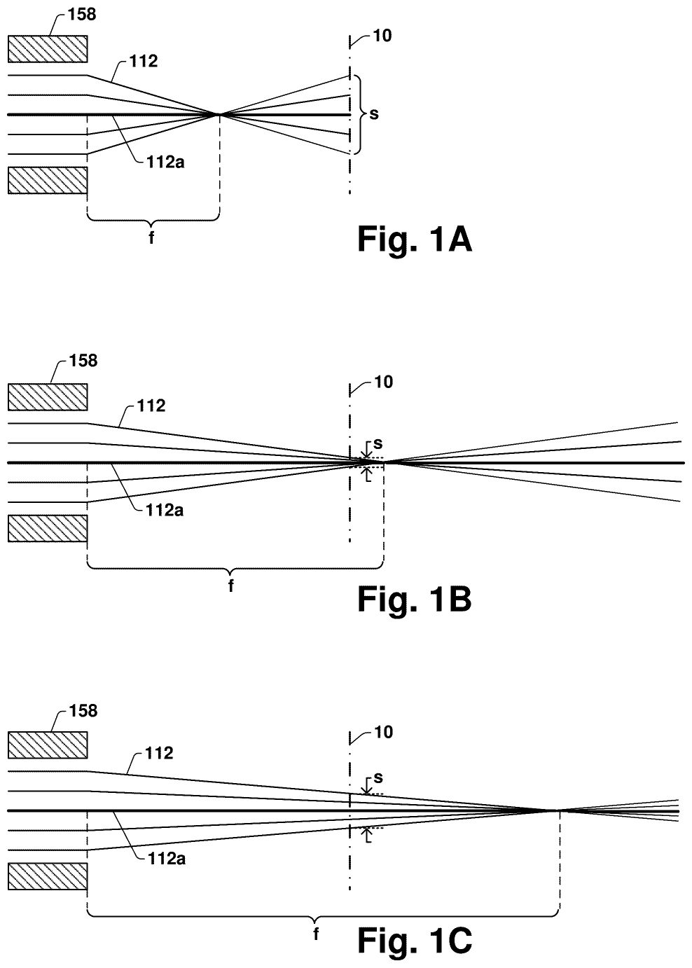

FIGS. 1A-1C illustrate an ion beam 112 after the deceleration stage of an ion implantation system in which the beam optics at and beyond the deceleration stage are not adjusted independently from the decel ratio. The only part of the ion implantation system shown in these figures is an electrode 158 of the deceleration stage. FIG. 1A illustrates the ion beam 112 for a highest decel ratio, FIG. 1B illustrates the ion beam 112 an intermediate decel ratio, and FIG. 1C illustrates the ion beam 112 for a lowest decel ratio. A beam path 112a of the ion beam 112 is a centerline of the ion beam 112. As shown in these figures, the focal length f of the ion beam 112 becomes shorter with increasing decel ratio, and the spot size S of the ion beam 112 at a fixed position implant plane 10 varies with the focal length f. The shape of the ion beam 112 is idealized in these figures. In practice the ion beam 112 is not perfectly focused and has non-linearity caused by the mutually repulsive forces of like charge ions. Nevertheless, the focal point of the ion beam 112 is defined by the position along the beam path 112a at which the ion beam 112 reaches a maximum in beam current density and the focal length f can be defined in terms of the focal point. The beam current density may be determined using a full width at half maximum (FWHM) standard, e.g., from the amount of beam current within an area over which the beam current is within half of its maximum, divided by that area.

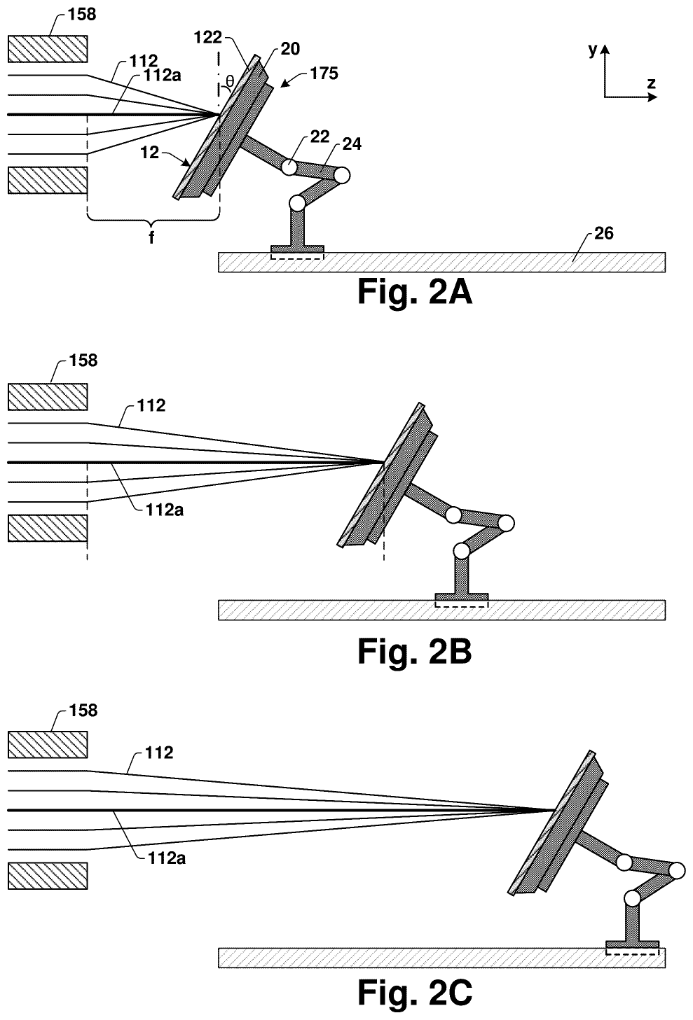

FIGS. 2A-2C illustrate a workpiece support 175 according to the present disclosure holding a workpiece 122 in the beam path 112a of the ion beam 112. The workpiece support 175 includes a chuck 20, may include one or more linkages 24, may include one or more joints 22, may include one or more rails 26, etc., or any other components suitable for positioning and moving the chuck 20. These components may include (but are not limited to), for example, a robotic arm, a linear stage, or a combination thereof. The chuck 20 may be an electrostatic chuck, a vacuum chuck, or a mechanical chuck. The chuck 20 is structured to hold a workpiece at a predetermined position on the chuck 20. In some embodiments, the chuck 20 is structured to hold wafers of a particular size. The workpiece support 175 controls the position of the chuck 20, the chuck 20 determines the position of the workpiece 122, and the implant plane 12 is a surface of the workpiece 122. Accordingly, the workpiece support 175 determines the position of the implant plane 12. As shown by FIGS. 2A-2C, the workpiece support 175 is able to translate the workpiece 122 so as to vary the position of the implant plane 12 along the beam path 112a. The workpiece support 175 may move the workpiece 122 (in each of the y, z and 0 directions) relative to a point of attachment of the workpiece support 175. The point of attachment is a point in a process chamber of an ion implantation system. In the illustrations of FIGS. 2A-2C, the ability of the workpiece support 175 to vary the position of the implant plane 12 is used to place the implant plane 12 at the focal point of the ion beam 112 for each of a high, an intermediate, and a low decel ratio (compare FIGS. 1A-1C).

In some embodiments, the workpiece support 175 has the range of motion to maintain the implant plane 12 at the focal point as the decel ratio is varied in the range from about 1:1 to about 5:1 while other operating parameters remain constant. In some embodiments, the workpiece support 175 has the range of motion to maintain the implant plane 12 at the focal point as the decel ratio is varied in the range from about 5:1 to about 30:1. In some embodiments, the workpiece support 175 has the range of motion to maintain the implant plane 12 at the focal point as the decel ratio is varied in the range from about 1:1 to about 30:1. In some embodiments, the workpiece support 175 is able to shorten or lengthen the beam path 112a to the implant plane 12 over a range of about 10 cm or more. In some embodiments, the workpiece support 175 is able to shorten or lengthen the beam path 112a to the implant plane 12 over a range of about 30 cm or more. In some embodiments, the workpiece support 175 is able to shorten or lengthen the beam path 112a to the implant plane 12 over a range of about 1 m or more.

As further illustrated by FIGS. 2A-2C, in some embodiments the workpiece support 175 is configured so that a tilt angle θ by which the implant plane 12 (equivalently, a vector normal to the implant plane 12) is tilted with respect to the beam path 112a of the ion beam 112 may be selected. In some embodiments, the workpiece support 175 allows the tilt angle θ to be set anywhere within a range from about 90° to about −90°. In some embodiments, the workpiece support 175 allows the tilt angle θ to be set anywhere within a range from about 45° to about-45°.

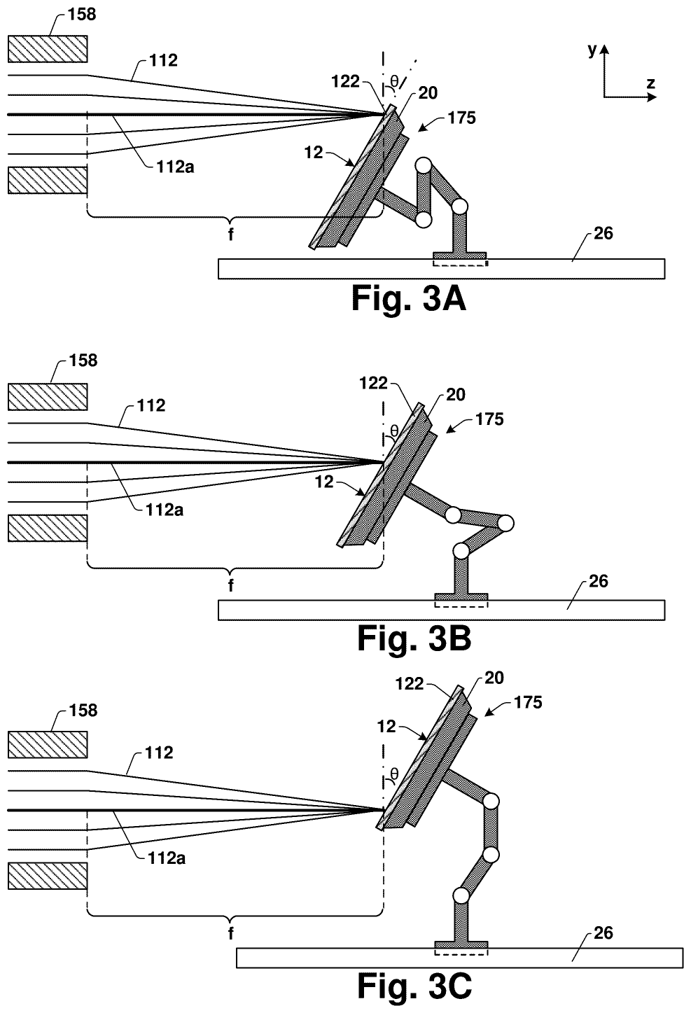

The relative positions of the workpiece 122 and the ion beam 112 are varied so that the ion beam 112 sweeps across the workpiece 122. As illustrated by FIGS. 3A-3C, in some embodiments the workpiece support 175 moves the workpiece 122 in the y-direction (up and down with respect to the orientation of FIGS. 2A-2C) to effectuate the y-direction sweep. The y-direction is the slow scan direction. As further shown by FIGS. 3A-3C, in some embodiments the workpiece support 175 moves the workpiece 122 so that the y-direction sweep is accomplished without changing the implant plane position regardless of the tilt angle θ. This is accomplished by moving the workpiece 122 parallel to the implant plane 12. This movement may be effectuated either through coordinated rotations about three joints 22, through a rail (not shown) behind the chuck 20, the like, or any other suitable mechanism.

The ion beam 112 may be a ribbon beam or a spot beam. A ribbon beam extending in the x-direction may be swept across the workpiece 122 just by moving the workpiece 122 in the y-direction. In some embodiments, however, the ion beam 112 is a spot beam. A spot beam is able to achieve higher beam current densities than a ribbon beam. The sweep in the x-direction may be effectuated by steering the ion beam 112. The x-direction is the fast scan direction.

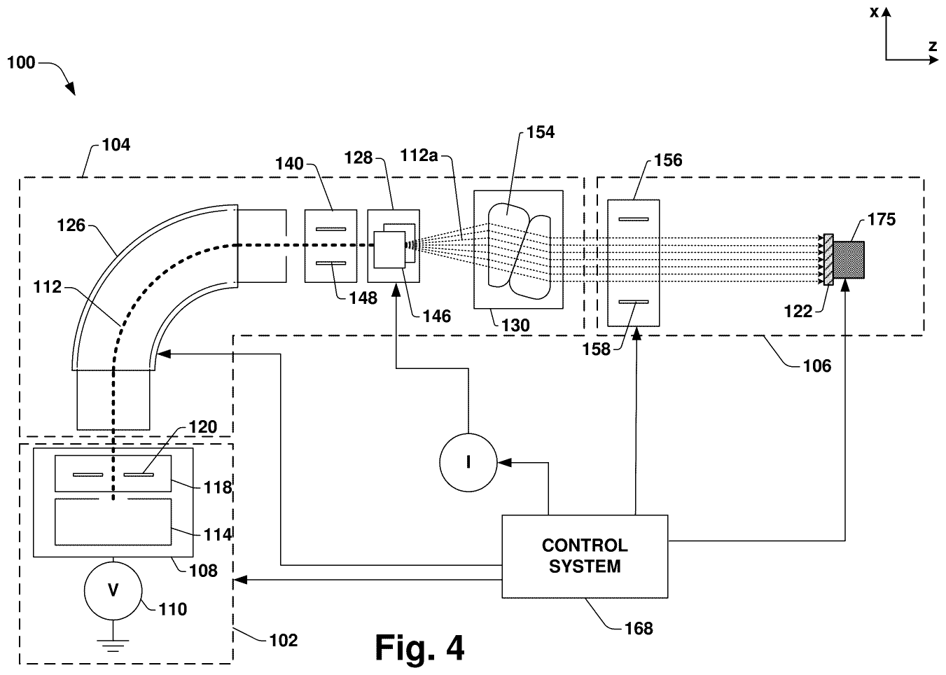

FIG. 4 illustrates an exemplary ion implantation system 100 that generates the ion beam 112 and steers the ion beam 112 to provide an x-direction sweep. The ion implantation system 100 includes a terminal 102, a beamline 104, and an end station 106. The terminal 102 includes an ion source 108 powered by a high voltage power supply 110 that produces ions that are extracted and formed into an ion beam 112. The beamline 104 filters, shapes and steers the ion beam 112, and the deceleration stage 156 slows the ion beam 112. The end station 106 includes the deceleration stage 156 and a process chamber in which the workpiece support 175 is disposed. The workpiece support 175 is configured to controllably translate the workpiece 122 toward or away from the deceleration stage 156.

The ion source 108 may include an arc chamber 114 and an ion extraction assembly 118. The arc chamber 114 is supplied with a gas that includes the species to be implanted. Within the arc chamber 114, electrons are generated from an electron source. The electron source may be a filament or cathode that is heated with a current from the high voltage power supply 110 to induce thermionic emission of electrons. The electrons may be induced to arc and ionize some of the gas in the arc chamber 114 generating a plasma. A magnetic field may be provided to contain the electrons in a spiral, which increases their travel time and thus their likelihood of ionizing gas molecules. The ions may be controllably extracted from the plasma and accelerated to the beamline energy by the ion extraction assembly 118. The ion extraction assembly 118 may include electrodes 120 that accelerate the extracted ions.

The beamline 104 may include a mass analyzer 126, a beam shaping and steering system 140, a scanning system 128, and a parallelizer 130. The mass analyzer 126 filters the ions based on charge-to-mass ratio so that after the mass analyzer 126 the ion beam 112 is a purified ion beam that includes only select ions. In the illustrated example, the mass analyzer 126 includes a bend through which the ions are deflected by a magnetic field. Ions having the wrong charge-to-mass ratio will be over-deflected or under-deflected so that only the ions having the desired charge-to-mass ratio continue down the beamline 104 from the mass analyzer 126.

The beam shaping and steering system 140 includes one or more electrical or magnetic lenses 148 that compresses and steer the ion beam 112. In some embodiments, the beam shaping and steering system 140 includes a first quadrupole magnet that squeezes the ion beam 112 in the x-direction (an x-quad) and a second quadrupole magnet that squeezes the ion beam 112 in the y-direction (an y-quad). The y-direction is into the page of FIG. 4. Other options for compressing and steering the ion beam 112 include electrostatic systems, other magnetic systems, and combinations thereof.

The scanning system 128 steers the ion beam 112 so that the beam path 112a sweeps across the x-direction. The scanning system 128 may include plates 146. The plates 146 may steer the ion beam 112 either electrically or magnetically. In some embodiments, the scanning system 128 sweeps the beam path 112a cyclically at a rate of about 500 Hz or more. These sweeps may be carried out without changing the position of the implant plane 12 (see FIG. 2A). The sweeps in the y-direction are at a slower rate, e.g., about 100 Hz or less. In some embodiments, the y-direction are about 1 Hz or less. Lower scan rates are associated with mechanical scans.

The scanned ion beam 112 may be passed through a parallelizer 130. In the illustrated example, the parallelizer 130 includes two dipole magnets 154. The two dipole magnets 154 may be substantially trapezoidal and oriented to mirror one another and bend the beam paths 112a into s-shapes. The parallelizer 130 has the effect of making all the beam paths 112a substantially parallel.

As previously discussed, the deceleration stage 156 is located within the end station 106 downstream from the parallelizer 130. The deceleration stage 156 includes one or more electrodes 158 that slow the ion beam 112 and focus the ion beam 112 into a converging stream. In some embodiments, the beamline 104 is maintained at a first potential and the deceleration stage 156 is maintained at a second potential, wherein the first potential corresponds to the beamline energy and the second potential corresponds to the implant beam energy. The deceleration stage 156 slows the ion beam 112. The deceleration stage 156 also includes beam focusing apparatus that focuses the ion beam 112. The apparatus that focuses the ion beam 112 may include the apparatus that slows the ion beam 112. In some embodiments, the deceleration stage 156 includes an Einzel lens.

A control system 168 (also called a controller) is further provided to control, communicate with, and/or adjust the ion source 108, the mass analyzer 126, the scanning system 128, the deceleration stage 156, and the workpiece support 175. The control system 168 may comprise a computer including a central processing unit and a memory system programmed with instructions for operating these and other components of the ion implantation system 100. For example, the control system 168 may determine the rate of ion production in the ion source 108, the beamline energy, the fast scan rate, the decel ratio, the slow scan rate, and the position of the implant plane 12 (see FIG. 2A). The control system 168 may receive a set of operating parameters constituting a recipe through which an operator may direct the ion implantation system 100 to conduct a specific and reproducible ion implantation operation.

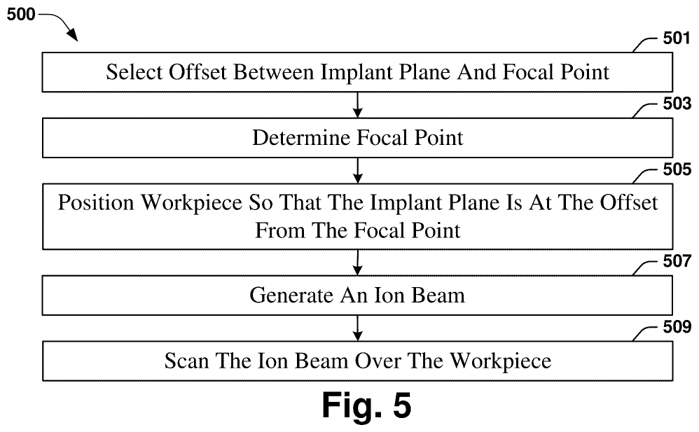

FIG. 5 provides a flow chart of a method 500 that may be implemented using the control system 168. The method begins with act 501, specifying a set of operating parameters that include an offset between the implant plane 12 and the focal point of the ion beam 112 (see FIG. 2A). The operating parameters may be provided to the control system 168 by an operator. In some embodiments, the operating parameters specify the offset is to be zero, which means the implant plane is at the focal point of the ion beam 112. In some embodiments, the other operating parameters include specifications that determine the decel ratio independently from the offset. In some embodiments, the operating parameters include the decel ratio explicitly. In some embodiments, the operating parameters include the beamline energy and the implant beam energy, which together determine the decel ratio. Another option is to specify the implant beam energy together with a set of operating parameters for the terminal 102 (see FIG. 4), whereby the beamline energy and the decel ratio are implicitly specified.

The method 500 continues with act 503, determining the focal point for the ion beam 112. In some embodiments, the control system 168 calculates where the focal point will be as a function of the decel ratio. The control system 168 may consider factors in addition to the decel ratio, such as operating parameters in the beamline 104 that have some effect on the focal point. In some embodiments, the control system 168 determines the focal point from a table lookup that depends on the decel ratio. In some embodiments, the operator determines the focal point and provides it to the control system 168. In some embodiments, the control system 168 detects the focal point.

Approaches to detecting the focal point include methods implemented with the workpiece 122 (or a dummy workpiece) in place and methods implemented without the workpiece 122 in place. Without the workpiece 122 in place, a beam current measuring device can be put on the implant plane 12 at the same location that the workpiece 122 will occupy.

In some embodiments, the beam current measuring device is a profiler that measures the beam profile (shape) in the y-direction. The rapid x-direction scans may continue while the beam profile in the y-direction is being measured. In some embodiments, the profiler is a multipoint profiler with components distributed in the y-direction. In some embodiments, the profiler is behind a narrow slit or opening that is scanned in the y-direction. The detecting element(s) of the profiler or other beam current measuring device may be a Faraday cup, a scanning wire, a phosphor screen profiler, a secondary emission profiler, a quadrupole array profiler, the like, or any other type of detector that can measure an ion beam current within a small area. The profile determines the beam width at the location of the detector. The focal point may be estimated from measurements at one z-direction position (distance along the beam path 112a). In some embodiments, however, the beam profile is measured at a plurality of positions with respect to the z-direction which allows for a more accurate determination of the focal point.

An alternative approach is measuring the beam current through a narrow slit or opening at the center of the ion beam 112, which is the beam path 112a. If the slit or opening is sufficiently narrow, the beam current through that slit or opening will reflect the beam current density. Taking measurements of the beam current density at a plurality of positions along the beam path 112a allows the focal point to be determined.

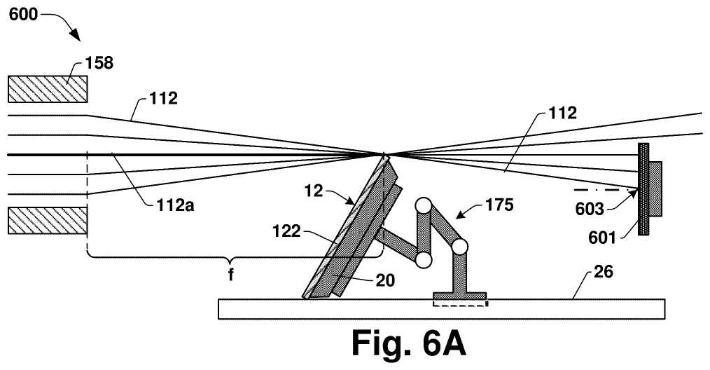

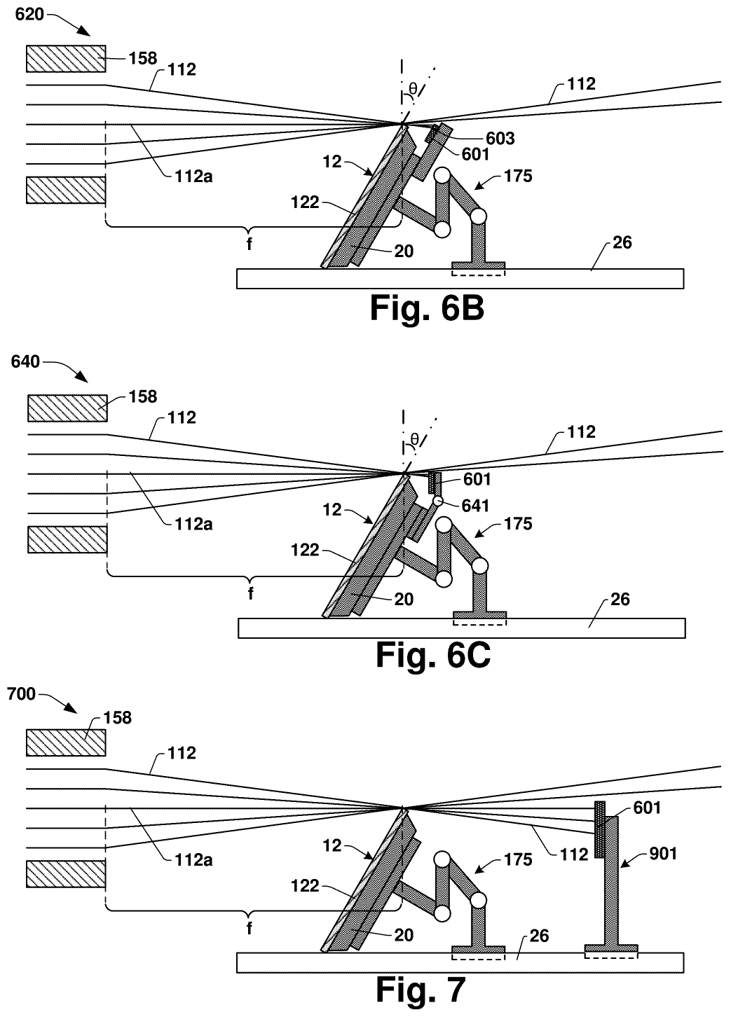

In some embodiments, the focal point is determined from the shadow cast by the ion beam 112 on the workpiece 122. Alternatively, the shadow of a dummy workpiece or other structure in place of the workpiece 122 may be used to make the determination. FIG. 6A illustrates an ion implantation system 600 that may be used to implement this method. As shown by FIG. 6A, in the course of ordinary scanning (x-direction or y-direction) the beam path 112a travels over the edge of the workpiece 122. The position 603 of the shadow of the ion beam 112 on the detector 601 depends on the focal point. The detector 601 may be any one of the types of detectors suitable for measuring the beam profile.

In the ion implantation system 600, the detector 601 is at a fixed position. If the detector 601 is at a fixed position, the position 603 of the shadow of the ion beam 112 on the detector 601 will vary over a wide range as the decel ratio is varied. The detector 601 would need to extend over this entire range to be operable for any decel ratio. In accordance another concept of the present disclosure, the detector 601 or the like is mounted to the workpiece support 175. FIG. 6B illustrates an ion implantation system 620 providing an example. The detector 601 is mounted to the workpiece support 175 and moves in unison with the workpiece 122. This configuration allows the detector 601 to be much smaller.

In the ion implantation system 620, the position 603 of the shadow of the ion beam 112 is a function of the tilt angle θ in addition to the focal length f. Also in the ion implantation system 620, the angle of incidence of the ion beam 112 on the detector 601 varies, which may have an adverse effect on the sensitivity of some types of detectors. In some embodiments, the workpiece support 175 has a joint 641 that allows the detector 601 to be faced normal to the beam path 112a regardless of the tilt angle θ. FIG. 6C illustrates an ion implantation system 640 providing an example of this type of system.

FIG. 7 illustrates an ion implantation system 700 in accordance with another embodiment. In this embodiment, the detector 601 is mounted on a detector holder 701 that is configured to translate the detector 601 in the z-direction so as to shorten or lengthen the path of the ion beam 112 to the detector 601 independently from the workpiece support 175. This provides the most versatile configuration. As the focal length f decreases and the workpiece 122 is moved up the beam path 112a, the detector 601 may also be moved up the beam path 112a to keep the ion beam 112 on the detector 601. As the focal length f increases and the workpiece 122 is down the beam path 112a, the detector 601 may also be moved down the beam path 112a to maintain the sensitivity of the detector 601 to variations in the focal length f.

The detector 601 of FIGS. 6A-6C and 7 is shown and described as being of the type used to determine the position of the beam shadow, however, it will be appreciated that other types of detectors are used behind workpieces in ion implantation systems and that similar considerations apply for positioning them. For example, in place of the detector 601 there may be a dose cup that is used to detect variations in the beam current. Accordingly, the mounting concepts of FIGS. 6A-6C and 7 may be applicable to any type of detector.

Returning to FIG. 5, the method 500 continues with act 505, which is positioning the workpiece 122 so that the implant plane 12 is at the offset from the focal point. Act 507 is generating the ion beam 112, wherein the ion beam has the focal point. The ion beam may comprise dopant ions. In some embodiments, the ion beam 112 comprises ions of a semiconductor. In some embodiments, the workpiece 122 is a semiconductor of the same type. Under these circumstances, the ion implantation may be a damage engineering implant.

Act 509 is scanning the ion beam 112 over the workpiece 122. The ion implantation system may scan the ion beam 112 in the x-direction. The workpiece support 175 (see FIG. 3A-3C) may move the workpiece 122 in the y-direction so that between the x-direction scans and the y-directions scans, the entire workpiece 122 is scanned on the implant plane 12.

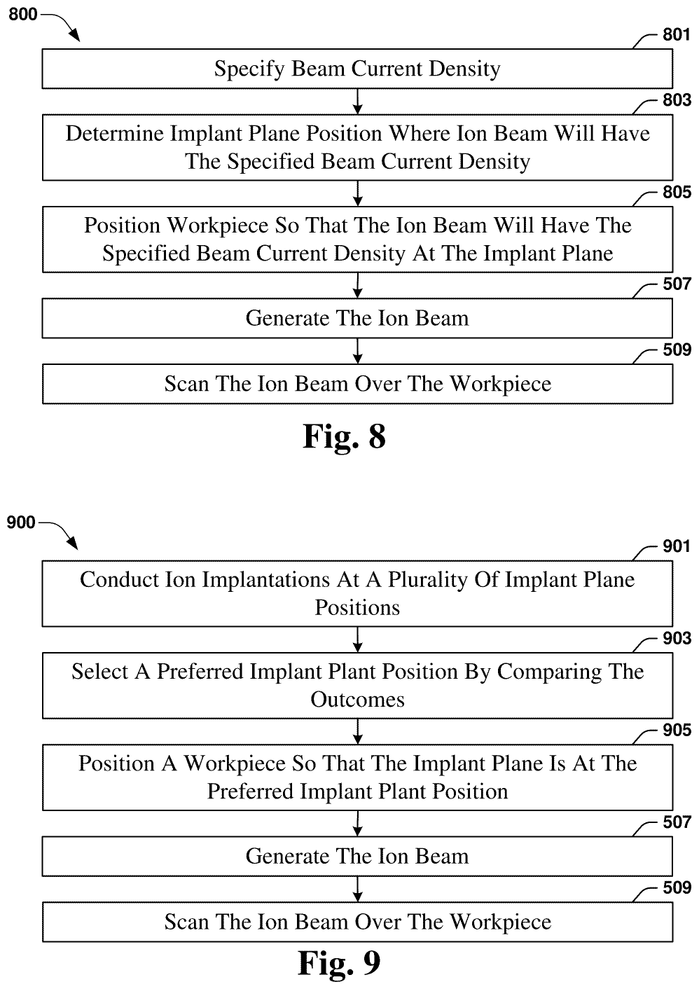

FIG. 8 provides a flow chart for a method 800 for operating the ion implantation system 100 of FIG. 4, or another ion implantation system provided by the present disclosure, in accordance with another embodiment. The method 800 begins with act 801. Act 801 may be similar to the act 501 of FIG. 5 except that the set of operating parameters include a beam current density instead of an offset. Act 803 is determining a position for the implant plane 12 at which the ion beam 112 will have the specified beam current density. Similar to act 503 of FIG. 5, the determination may include calculation, a table look-up, or measurement. Act 805 is positioning the workpiece 122 so that the ion beam 112 will have the specified beam current density at the implant plane 12. The method 800 then continues as does the method 500 with act 507, generating the ion beam 112, and act 509, scanning the ion beam 112 over the workpiece 122.

FIG. 9 provides a flow chart for a method 900 of operating an ion implantation system, in accordance with still another embodiment of the disclosure. The method 900 begins with act 901, conducting ion implantations at a plurality of implant plane positions while other operating parameters are consistently maintained. The implants may be carried out on different workpieces 122, or they may be carried out on different parts of one workpiece. In some embodiments of the method, the workpiece 122 is moved along the beam path 112a while ion implantation is taking place.

Act 903 is comparing the outcomes of the ion implantations at the various implant plane positions and selecting a preferred implant plane position based on the comparison. The beam current density varies with implant plane position, and this may affect the outcomes. For example, there may be a beam current density threshold at which excessive thermal damage to a photoresist or other structure on the workpiece 122 is observed. The implant plane position may be selected so that the beam current density is maximized while remaining at a margin below that threshold. Act 905 is positioning a workpiece 122 at the preferred position, act 507 is generating the ion beam 112, and act 509 is scanning the ion beam 112 over the workpiece 122.

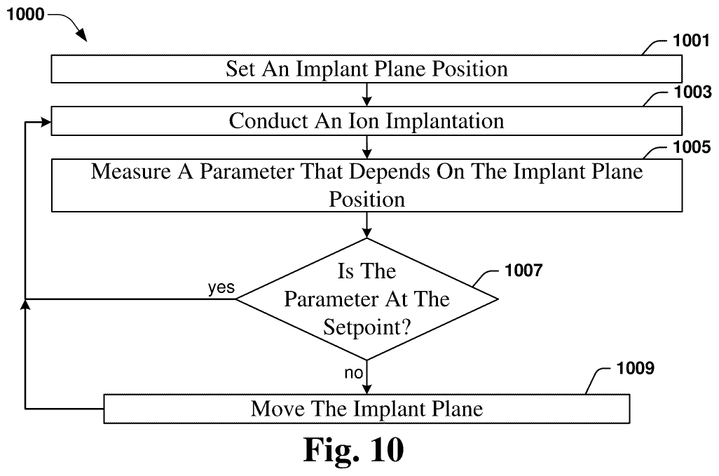

FIG. 10 provides a flow chart for a method 1000 of operating an ion implantation system in accordance with another embodiment of the present disclosure. The method 1000 is an example in which the implant plane position is adjusted with feedback control. The method 1000 begins with act 1001, setting an implant plane position. Act 1003 is conducting an ion implantation with a workpiece 122 at the current implant plane position. In some embodiments, this comprises a full scan of the ion beam 112 over the workpiece 122. In some embodiments, this is only a partial scan.

Act 1005 is measuring a parameter that depends on the implant plane position. This parameter could be, for example, a beam current density, a position of a shadow of the workpiece 122, a thermal or optical effect related to the beam current density, the like, or any other suitable parameter. Act 1007 is determining whether the parameter is satisfactorily close to a set point. If it is, the method 1000 continues with act 1003 and further ion implantation is carried out either on the same workpiece or a different workpiece. If the parameter is not satisfactorily close to the set point, the implant plane position is adjusted with act 1009 and then ion implantation is continued.

Some aspects of the present disclosure relate to an ion implantation system that includes an ion source configured to generate an ion beam, an end station including a workpiece support that defines an implant plane, and a beam focusing apparatus that directs the ion beam along a path to the implant plane. The workpiece support is configured to selectively translate the implant plane along the path so as to shorten or lengthen the path.

In some embodiments, the ion implantation system further includes a deceleration stage configured to decelerate the ion beam from a first energy level to a second energy level. In some embodiments, the system includes a beam steering apparatus that scans the ion beam in a fast scan direction, and the workpiece support is configured to move a workpiece across the ion beam in a slow scan direction. In some embodiments, the workpiece support is configured to move the workpiece in the slow scan direction while holding the workpiece at a tilt with respect to the ion beam without altering the implant plane.

In some embodiments, the system further includes a controller configured to control the workpiece support. The controller is programmed to command the workpiece support to translate the implant plane to a position that depends on the decel ratio. In some embodiments, the controller is programmed to accept as input a fixed offset and make the position of the implant plane at the fixed offset from a focal point for the ion beam. In some embodiments, the controller is programmed to determine the focal point for the ion beam as a function of the decel ratio. In some embodiments, the controller is programmed to determine the position, and the position is where a current density of the ion beam has a maximum. In some embodiments, the controller is programmed to accept as input an ion beam current density and determine the implant plane position as the position where the ion beam reaches the ion beam current density.

In some embodiments, the ion beam has a focal point that depends on the decel ratio and the implant plane can be set to the focal point for ratios in the range from 1:1 to 5:1. In some embodiments, the ion beam has a focal point that depends on the decel ratio and the implant plane can be set to the focal point for ratios in the range from 5:1 to 30:1. In some embodiments, the ion beam is a spot beam. In some embodiments, the system includes a controller configured to control the workpiece support and the controller is programmed to accept as input an implant plane position and to command the workpiece support to translate the implant plane to the implant plane position.

Some aspects of the present disclosure relate to an ion implantation system that includes an ion source, a mass analyzer that filters ions extracted from the ion source to provide a stream of purified ions, a scanning system that scans the stream of purified ions to provide a scanning stream, a deceleration stage that slows the purified ions in the scanning stream from a first energy level to a second energy level to provide an ion beam, wherein a decel ratio is a ratio of the first energy level to the second energy level, a workpiece support configured to hold a wafer in a path of the ion beam, and a controller that receives a set of operating parameters. The set of operating parameters determine the decel ratio, the ion beam has a current density that varies along the path, and the control directs the workpiece support to position the wafer at a selected position along the path. The selected position varies in relation to the decel ratio.

In some embodiments, the workpiece support is configured to sweep the wafer in a first direction and the scanning system is configured to scan the ion beam across the wafer in a second direction, which is transverse to the first direction. In some embodiments, the workpiece support is configured to hold the wafer at a tilt with respect to the path and to sweep the wafer at the tilt in the first direction without changing the position of the wafer along the path. In some embodiments, the set of operating parameters specify a difference between the selected position and a focal point of the ion beam. In some embodiments, the selected position is at a focal point of the ion beam. In some embodiments, the controller estimates a location of a focal point of the ion beam in in determining the selected position. In some embodiments, the controller uses an estimate of the current density at the selected position along the path in determining the selected position along the path.

Some aspects of the present disclosure relate to a method of operating an ion implantation system. The method includes selecting a decel ratio, selecting an implant plane position from a range of implant plane positions, positioning a workpiece according to the implant plane position, generating ions, accelerating the ions to the first energy level, filtering the ions and shaping them into an ion beam at the first energy level, and decelerating the ions to the second energy level and directing the ion beam toward the workpiece. The ion beam strikes the workpiece at the implant plane position.

In some embodiments, the implant plane position is a function of the decel ratio. In some embodiments, the implant plane position is at a focal point for the ion beam. In some embodiments, the method further includes selecting a beam current density, and implant plane position is selected so that the ion beam has the beam current density at the implant plane position. In some embodiments, the method further includes selecting an offset, and the implant plane position is made to be at the offset from a focal point for the ion beam. In some embodiments, the method further includes moving the workpiece so that the ion beam sweeps across the workpiece while continuing to strike the workpiece at the implant plane position, even where the workpiece is at a tilt with respect to the ion beam.

In some embodiments, the method further includes determining a location of an edge of a shadow of the workpiece and selecting the implant plane position in dependence on the location of the edge. In some embodiments, selecting the implant plane position in dependence on the location of the edge comprises determining a focal point of the ion beam from the location of the edge.

Some aspects of the present disclosure relate to an ion implantation system, comprising that includes an ion source that generates ions, an ion extraction assembly that accelerates the ions to a first energy level, a beamline system that shapes the accelerated ions into a beam, a deceleration system that selectively reduces an energy of the beam, wherein the beam has a focal point downstream from the deceleration system, a process chamber, and a workpiece support in the process chamber, wherein the workpiece support has a structure that determines a held workpiece position. In some embodiments, the held workpiece position is electronically movable along the path of the beam. In some embodiments, the system includes a control programed with instructions for setting the held workpiece position. In some embodiments, the system includes a detector positioned to analyze a shadow of the beam cast by the workpiece. In some embodiments, the detector is mounted to the workpiece support. In some embodiments, the mount includes a mechanism for tilting the detector at an angle with respect to the workpiece.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. In addition, while a particular feature may have been disclosed with respect to only one of several embodiments, such feature may be combined with one or more other features of the other embodiments as may be desired or advantageous for a given application.

What is claimed is:

1. An ion implantation system, comprising:
an ion source configured to generate an ion beam;
an end station including a workpiece support that defines an implant plane; and
a beam focusing apparatus that directs the ion beam along a path to the implant plane;
wherein the workpiece support is configured to selectively translate the implant plane along the path so as to shorten or lengthen the path.

2. The ion implantation system of claim 1, further comprising a deceleration stage configured to decelerate the ion beam from a first energy level to a second energy level, wherein a decel ratio is a ratio of the first energy level to the second energy level.

3. The ion implantation system of claim 2, further comprising a beam steering apparatus that scans the ion beam in a fast scan direction, wherein the workpiece support is configured to move a workpiece across the ion beam in a slow scan direction.

4. The ion implantation system of claim 3, wherein the workpiece support is configured to move the workpiece in the slow scan direction while holding the workpiece at a tilt with respect to the ion beam without altering the implant plane.

5. The ion implantation system of claim 2, further comprising a controller configured to control the workpiece support, wherein the controller is programmed to command the workpiece support to translate the implant plane to a position that depends on the decel ratio.

6. The ion implantation system of claim 2, wherein the ion beam is a spot beam.

7. The ion implantation system of claim 1, further comprising a controller configured to control the workpiece support, wherein the controller is programmed to accept as input an implant plane position and to command the workpiece support to translate the implant plane to the implant plane position.

8. An ion implantation system, comprising:
an ion source;
a mass analyzer that filters ions extracted from the ion source to provide a stream of purified ions;
a scanning system that scans the stream of purified ions to provide a scanning stream;
a deceleration stage that slows the purified ions in the scanning stream from a first energy level to a second energy level to provide an ion beam, wherein a decel ratio is a ratio of the first energy level to the second energy level;
a workpiece support configured to hold a wafer in a path of the ion beam; and
a controller that receives a set of operating parameters;
wherein the set of operating parameters determine the decel ratio;
the ion beam has a current density that varies along the path; and
the control directs the workpiece support to position the wafer at a position along the path, wherein the controller is configured to determine the position in relation to the decel ratio.

9. The ion implantation system of claim 8, wherein:
the workpiece support is configured to sweep the wafer in a first direction and the scanning system is configured to scan the ion beam across the wafer in a second direction, which is transverse to the first direction; and
the workpiece support is configured to hold the wafer at a tilt with respect to the path and to sweep the wafer at the tilt in the first direction without changing the position of the wafer along the path.

10. The ion implantation system of claim 8, wherein the set of operating parameters specify a difference between the position of the wafer along the path and a focal point of the ion beam.

11. The ion implantation system of claim 8, wherein the position of the wafer along the path is at a focal point of the ion beam.

12. The ion implantation system of claim 8, wherein the controller estimates a location of a focal point of the ion beam in determining the position of the wafer along the path.

13. The ion implantation system of claim 8, wherein the controller uses an estimate of the current density at the position of the wafer along the path along the path in determining the position of the wafer along the path along the path.

14. A method of operating an ion implantation system, the method comprising:
selecting a decel ratio, the decel ratio being a ratio of a first ion energy level to a second ion energy level;
determining an implant plane position from a range of implant plane positions enabled by the ion implantation system;
positioning a workpiece according to the implant plane position;
generating ions;
accelerating the ions to the first ion energy level;
filtering the ions and shaping them into an ion beam at the first ion energy level; and
decelerating the ions to the second ion energy level and directing the ion beam toward the workpiece;
wherein the ion beam strikes the workpiece at the implant plane position.

15. The method of claim 14, wherein the implant plane position is determined by a function of the decel ratio.

16. The method of claim 15, wherein the implant plane position is at a focal point for the ion beam.

17. The method of claim 15, further comprising selecting a beam current density, wherein the ion beam has the beam current density at the implant plane position.

18. The method of claim 14, further comprising selecting an offset, wherein the implant plane position is at an offset from a focal point for the ion beam.

19. The method of claim 14, further comprising moving the workpiece so that the ion beam sweeps across the workpiece while continuing to strike the workpiece at the implant plane position, wherein the workpiece is at a tilt with respect to the ion beam.

20. The method of claim 14, further comprising determining a location of an edge of a shadow of the workpiece, wherein the implant plane position is determined according to the location of the edge.
